(19) United States
(12) Patent Application Publication
(10) Pub. No.: US 2024/0243050 A1
(43) Pub. Date: Jul. 18, 2024

(54) SEMICONDUCTOR PACKAGE INCLUDING AN INTERPOSER

(71) Applicant: SAMSUNG ELECTRONICS CO., LTD., Suwon-Si (KR)

(72) Inventor: HAE-JUNG YU, Suwon-si (KR)

(21) Appl. No.: 18/503,690

(22) Filed: Nov. 7, 2023

(30) Foreign Application Priority Data
Jan. 12, 2023 (KR) 10-2023-0004796

(51) Int. Cl. H01L 23/498; H01L 21/66; H01L 23/00; H01L 23/31; H01L 25/10; H10B 80/00

(52) U.S. Cl. CPC H01L 23/49822; H01L 22/32; H01L 23/3135; H01L 24/16; H01L 24/32; H01L 24/73; H01L 25/105; H10B 80/00; H01L 2224/16145; H01L 2224/16227; H01L 2224/16238; H01L 2224/32145; H01L 2224/32225; H01L 2224/73204; H01L 2924/1431; H01L 2924/1436; H01L 2924/1438

(57) ABSTRACT

A semiconductor package includes a package substrate, an interposer disposed on the package substrate, and a first semiconductor chip disposed on the interposer. The interposer includes a first semiconductor substrate and a first dielectric layer disposed on the first semiconductor substrate. The first dielectric layer includes a first scribe lane region. The first scribe lane region is below the first semiconductor chip along a first direction that is perpendicular to a top surface of the first semiconductor substrate. The first scribe lane region is spaced apart from a lateral surface of the interposer.

### CROSS-REFERENCE TO RELATED APPLICATION

This U.S. nonprovisional application claims priority under 35 U.S.C. § 119 to Korean Patent Application No. 10-2023-0004796, filed on Jan. 12, 2023 in the Korean Intellectual Property Office, the disclosure of which is hereby incorporated by reference in its entirety.

### TECHNICAL FIELD

The present inventive concepts relate to a semiconductor package, and more particularly, to a semiconductor package including an interposer.

### DISCUSSION OF THE RELATED ART

In accordance with the rapid development of the electronics industry and the growing needs of users, electronic devices are being designed to have a compact size, perform multiple functions, and have a high capacity. To meet this need, semiconductor packages have been designed to include a plurality of semiconductor chips.

However, failure rates for printed circuit boards including highly integrated semiconductor packages with multiple semiconductor chips can be relatively high. To solve the problem, semiconductor packages are being developed to use an interposer to connect the plurality of semiconductor chips to each other.

### SUMMARY

A semiconductor package includes a package substrate; an interposer disposed on the package substrate; and a first semiconductor chip disposed on the interposer. The interposer includes a first semiconductor substrate; and a first dielectric layer disposed on the first semiconductor substrate. The first dielectric layer includes a first scribe lane region. The first scribe lane region is below the first semiconductor chip along a first direction that is perpendicular to a top surface of the first semiconductor substrate. The first scribe lane region is spaced apart from a lateral surface of the interposer.

A semiconductor package includes a package substrate; an interposer disposed on the package substrate; and a semiconductor chip disposed on the interposer. The interposer includes a first semiconductor substrate; and a first dielectric layer disposed on the first semiconductor substrate. The first dielectric layer includes a wiring region; a scribe lane region that at least partially surrounds the wiring region; and a dummy region that at least partially surrounds the scribe lane region. In a plan view, at least a portion of the dummy region surrounds the semiconductor chip.

A semiconductor package includes a package substrate; an interposer disposed on the package substrate; a logic chip disposed on the package substrate; and a pair of sub-semiconductor packages that are spaced apart in a first direction from each other across the logic chip. Each of the sub-semiconductor packages includes a base chip; a memory chip stack disposed on the base chip; and a first mold structure that covers the base chip and the memory chip stack. The interposer includes an inspection pattern disposed on an upper portion of the interposer. The inspection pattern includes a test element group and/or a wafer alignment key. A second spacing distance between the inspection pattern and a lateral surface of the interposer is greater than a first spacing distance between a lateral surface of the base chip and an extension surface that extends from the lateral surface of the interposer. The lateral surface of the base chip is adjacent to the extension surface.

### BRIEF DESCRIPTION OF DRAWINGS

A more complete appreciation of the present disclosure and many of the attendant aspects thereof will be readily obtained as the same becomes better understood by reference to the following detailed description when considered in connection with the accompanying drawings, wherein:

FIG. 1 is a plan view showing a semiconductor package according to some embodiments of the present inventive concepts;

FIG. 2 is a simplified cross-sectional view taken along line I-I′ of FIG. 1;

FIG. 3 is an enlarged view showing section AA of FIG. 2;

FIG. 4 is a cross-sectional view showing a semiconductor package according to some embodiments of the present inventive concepts;

FIG. 5 is a cross-sectional view showing a semiconductor package according to some embodiments of the present inventive concepts;

FIG. 6 is a cross-sectional view showing a semiconductor package according to some embodiments of the present inventive concepts;

FIG. 7 is a plan view showing a wafer prior to sawing;

FIG. 8 is an enlarged view showing section BB of FIG. 7; and

FIGS. 9A and 9B are cross-sectional views showing a method of fabricating an interposer.

### DETAILED DESCRIPTION OF EMBODIMENTS

The following will now describe some embodiments of the present inventive concepts in conjunction with the accompanying drawings.

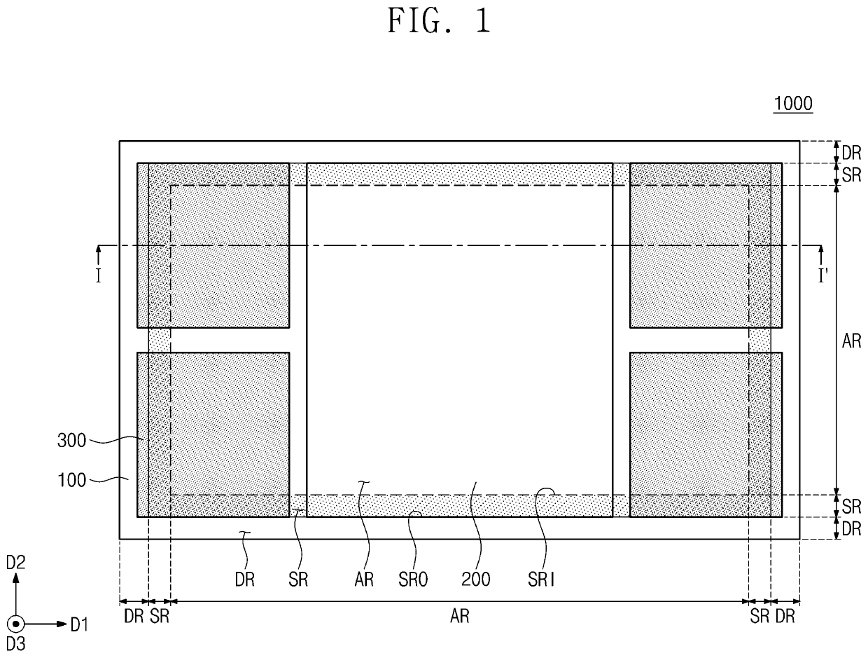

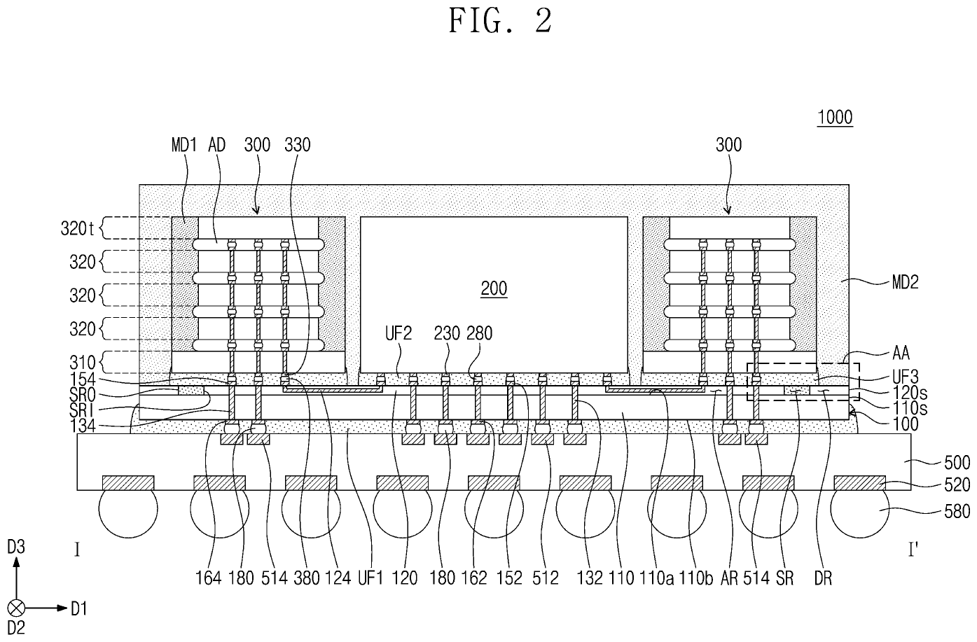

FIG. 1 is a plan view showing a semiconductor package according to some embodiments of the present inventive concepts. FIG. 2 is a simplified cross-sectional view taken along line I-I′ of FIG. 1. For clarity of configuration, FIG. 2 omits some components of FIG. 1 but it is to be assumed that these omitted components may be part of the semiconductor package of FIG. 2.

Referring to FIGS. 1 and 2, a semiconductor package 1000, according to some embodiments of the present inventive concepts, may include a package substrate 500, an interposer 100, a first semiconductor chip 200, and a plurality of sub-semiconductor packages 300.

The package substrate 500 may be, for example, a printed circuit board (PCB).

The package substrate 500 may include first upper metal pads 512, second upper metal pads 514, lower metal pads 520, metal lines, and external connection terminals 580. The first upper metal pads 512 and the second upper metal pads 514 may be disposed on an upper portion of the package substrate 500, and the lower metal pads 520 may be disposed on a lower portion of the package substrate 500. The first upper metal pads 512 may be electrically connected to the first semiconductor chip 200, and the second upper metal pads 514 may be electrically connected to the sub-semiconductor packages 300. The metal lines may electrically connect the first and second upper metal pads 512 and 514 to the lower metal pads 520. The external connection terminals 580 may be correspondingly disposed on the lower metal pads 520. The external connection terminals 580 may include an electrically conductive material such as solder.

The interposer 100 may be disposed on the package substrate 500. The interposer 100 may include a first semiconductor substrate 110, first through electrodes 132, second through electrodes 134, an upper dielectric layer 120, a wiring structure 124, first upper pads 152, second upper pads 154, first lower pads 162, and second lower pads 164.

The first semiconductor substrate 110 may include a semiconductor, such as silicon or germanium, and may be, for example, a silicon substrate. The first semiconductor substrate 110 may have a first surface 110a and a second surface 110b that face each other. The first surface 110a and the second surface 110b may respectively correspond to a top surface and a bottom surface of the first semiconductor substrate 110.

In this disclosure, a first direction D1 indicates one direction parallel to the first surface 110a of the first semiconductor substrate 110. A second direction D2 indicates one direction that is parallel to the first surface 110a of the first semiconductor substrate 110 and intersects the first direction D1. A third direction D3 indicates one direction that is perpendicular to the first surface 110a of the first semiconductor substrate 110.

The upper dielectric layer 120 may be provided on the first surface 110a of the first semiconductor substrate 110. The upper dielectric layer 120 may be a dielectric layer, such as a silicon oxide layer. The upper dielectric layer 120 is illustrated as one layer, but actually may be formed of a plurality of dielectric layers.

The upper dielectric layer 120 may include a wiring region AR, a scribe lane region SR, and a dummy region DR.

The wiring region AR may occupy a portion larger than all the other portions of the upper dielectric layer 120. The wiring region AR may be an area where the wiring structure 124 is disposed.

The scribe lane region SR may have a tetragonal ring shape that at least partially surrounds the wiring region AR. The scribe lane region SR may include an inner edge SRI and an outer edge SRO. According to some embodiments, the inner edge SRI of the scribe lane region SR may be consistent with a boundary between the scribe lane region SR and the wiring region AR. Alternatively, the upper dielectric layer 120 may further include an intermediate region that is interposed between the scribe lane region SR and the wiring region AR. A crack detection circuit may be formed on the first semiconductor substrate 110 that vertically overlaps the intermediate region.

As discussed below, the scribe lane region SR may be an area where a test element group, an inspection pattern such as a wafer alignment key, and a stress buffer such as a seal ring are disposed. For example, the scribe lane region SR may be an area where a test element group for measuring performance of the interposer 100 and any other suitable test patterns are formed. For another example, the scribe lane region SR may be an area where a pattern for mask alignment is formed.

The dummy region DR may have a tetragonal ring shape that at least partially surrounds the scribe lane region SR, and may be spaced apart from the wiring region AR across the scribe lane region SR. The wiring structure 124 and the inspection pattern 700 may be a metal pattern including metal such as copper and/or aluminum, and the dummy region DR may be an area where no metal pattern is disposed.

The wiring structure 124 may electrically connect the first semiconductor chip 200 to the sub-semiconductor packages 300.

The first through electrodes 132 and the second through electrodes 134 may penetrate the first semiconductor substrate 110 that vertically overlaps the wiring region AR. The first through electrodes 132 may be electrically connected to the first semiconductor chip 200 or may vertically overlap the first semiconductor chip 200. The second through electrodes 134 may be electrically connected to the sub-semiconductor package 300 or may vertically overlap the sub-semiconductor package 300.

The first upper pads 152 may be correspondingly disposed on one ends of the first through electrodes 132, and the second lower pads 162 may be correspondingly disposed on opposite ends of the first through electrodes 132. The second upper pads 154 may be correspondingly disposed on one ends of the second through electrodes 134, and the second lower pads 164 may be correspondingly disposed on opposite ends of the second through electrodes 134.

First connection terminals 180 may be correspondingly disposed on the first lower pads 162 and the second lower pads 164. The first connection terminals 180 may include an electrically conductive material such as solder. The first lower pad 162 may be connected through the first connection terminal 180 to the first upper metal pad 512. The second lower pad 164 may be connected through the first connection terminal 180 to the second upper metal pad 514.

A first underfill pattern UF1 may be interposed between a second surface 100b of the interposer 100 and a top surface of the package substrate 500. The first underfill pattern UF1 may include, for example, an epoxy resin composition. The first underfill pattern UF1 may fill a space between the first connection terminals 180.

The interposer 100 may be provided thereon with the first semiconductor chip 200 and a plurality of sub-semiconductor packages 300. For example, the first semiconductor chip 200 may be positioned on a central portion of the interposer 100. The sub-semiconductor packages 300 may be spaced apart in the first direction D1 from each other across the first semiconductor chip 200. As shown in FIG. 1, two sub-semiconductor packages 300 may be disposed adjacent to one lateral surface of the first semiconductor chip 200, and another two sub-semiconductor packages 300 may be disposed adjacent to another lateral surface of the first semiconductor chip 200. Neighboring sub-semiconductor packages 300 may be spaced apart from each other in the second direction D2.

According to some embodiments, three sub-semiconductor packages 300 may be disposed adjacent to one lateral surface of the first semiconductor chip 200, and another three sub-semiconductor packages 300 may be disposed adjacent to another lateral surface of the first semiconductor chip 200. A plurality of sub-semiconductor package 300 may be provided, and the plurality of sub-semiconductor packages 300 may be arranged in various ways.

The sub-semiconductor packages 300 may be disposed on an outer portion of the interposer 100. The first semiconductor chip 200 may be disposed on the central portion and the outer portion of the interposer 100.

The first semiconductor chip 200 may be a logic chip. The first semiconductor chip 200 may be, for example, one of a central processing unit (CPU), a graphic processing unit (GPU), and an application specific integrated circuit (ASIC). The first semiconductor chip 200 may transmit signals to the sub-semiconductor package 300 and/or to receive signals from the sub-semiconductor package 300.

The first semiconductor chip 200 may include first chip pads 230 in a lower portion thereof. Second connection terminals 280 may be correspondingly disposed on the first chip pads 230. The second connection terminals 280 may include an electrically conductive material such as solder. A second underfill pattern UF2 may be interposed between the interposer 100 and a bottom surface of the first semiconductor chip 200. The second underfill pattern UF2 may fill a space between the second connection terminals 280. The second underfill pattern UF2 may include, for example, an epoxy resin composition. The second underfill pattern UF2 may be disposed on the dummy region DR, the scribe lane region SR, and the wiring region AR.

The sub-semiconductor package 300 may include a second semiconductor chip 310, third semiconductor chips 320 and 320t disposed on the second semiconductor chip 310, and a first mold structure MD1. In this disclosure, the second semiconductor chip 310 may be a base chip, and the third semiconductor chips 320 and 320t may be called memory chips.

The base chip 310 may be a logic chip. The base chip 310 may be, for example, a memory controller.

The memory chips 320 and 320t may be stacked in the third direction D3 on the base chip 310. The memory chips 320 and 320t may be the same kind of semiconductor chip having the same circuit. The memory chips 320 and 320t may each be one of DRAM and NAND Flash.

The base chip 310 and the memory chips 320 may include through electrodes. An uppermost one 320t of the memory chips 320 and 320t might not include through electrodes therein. According to some embodiments, the uppermost memory chip 320t may include through electrodes. The through electrodes of the base chip 310 may be electrically connected through micro-bumps to the through electrodes of the memory chip 320 that neighbors the base chip 310. The through electrodes of neighboring memory chips 320 may be electrically connected to each other through micro-bumps.

Adhesion layers AD may be interposed between the base chip 310 and its neighboring memory chip 320 and between neighboring memory chips 320. The adhesion layers AD may each be, for example, a non-conductive film (NCF) including polymer.

The first mold structure MD1 may cover a top surface of the base chip 310, lateral surfaces of the memory chips 320 and 320t, and lateral surfaces of the adhesion layers AD. A top surface of the uppermost memory chip 320t may be exposed by the first mold structure MD1. The first mold structure MD1 may include an epoxy molding compound (EMC). The semiconductor package 1000 may further include a second mold structure MD2 provided on the interposer 100. The second mold structure MD2 may cover a top surface of the interposer 100, the first semiconductor chip 200, and the sub-semiconductor packages 300.

The base chip 310 may include, on its lower portion, second chip pads 330 that are correspondingly connected to the through electrodes. Third connection terminals 380 may be correspondingly disposed on the second chip pads 330. A third underfill pattern UF3 may be interposed between the top surface of the interposer 100 and a bottom surface of the base chip 310. The third underfill pattern UF3 may fill a space between the third connection terminals 380. The third underfill pattern UF3 may include, for example, an epoxy resin composition. The third underfill pattern UF3 may be disposed on the dummy region DR, the scribe lane region SR, and the wiring region AR.

According to some embodiments, the sub-semiconductor package 300 may be replaced with a fourth semiconductor chip. The fourth semiconductor chip may be of a different type from the first semiconductor chip 200. For example, when the first semiconductor chip 200 is a logic chip, the fourth semiconductor chip may be a memory chip. For another example, when the first semiconductor chip 200 is a memory chip, the fourth semiconductor chip may be a logic chip.

The scribe lane region SR may be disposed in the third direction D3 below the sub-semiconductor package 300. The scribe lane region SR may be disposed below the second semiconductor chip 310.

In a plan view, as shown in FIG. 1, the scribe lane region SR may completely overlap the sub-semiconductor package 300. For example, both of the inner and outer edges SRI and SRO of the scribe lane region SR may completely overlap the sub-semiconductor package 300.

According to some embodiments, a portion of the scribe lane region SR may overlap the sub-semiconductor package 300, and a remainder of the scribe lane region SR may be exposed by the sub-semiconductor package 300. For example, the inner edge SRI of the scribe lane region SR may overlap the sub-semiconductor package 300, and the outer edge SRO of the scribe lane region SR may be exposed by the sub-semiconductor package 300.

The scribe lane region SR may be disposed below the second semiconductor chip 310. For example, the inner edge SRI of the scribe lane region SR may vertically overlap the second semiconductor chip 310, and the outer edge SRO of the scribe lane region SR may vertically overlap or might not overlap the second semiconductor chip 310. The dummy region DR may be positioned in a diagonal direction with respect to the first semiconductor chip 200.

The dummy region DR may be positioned in a diagonal direction with respect to the sub-semiconductor package 300. The dummy region DR may be positioned in a diagonal direction with respect to the second semiconductor chip 310.

For example, both of the inner and outer edges SRI and SRO of the scribe lane region SR may surround the second semiconductor chip 310 without overlapping the second semiconductor chip 310. When the outer edge SRO of the scribe lane region SR overlaps the sub-semiconductor package 300, a portion of the dummy region DR may overlap the sub-semiconductor package 300. In this configuration, in a plan view, at least a portion of the dummy region DR may surround the first semiconductor chip 200 and the sub-semiconductor packages 300. A lateral surface 110s of the first semiconductor substrate 110 may be coplanar with a lateral surface 120s of the upper dielectric layer 120. The lateral surface 120s of the upper dielectric layer 120 may correspond to an outer edge of the dummy region DR.

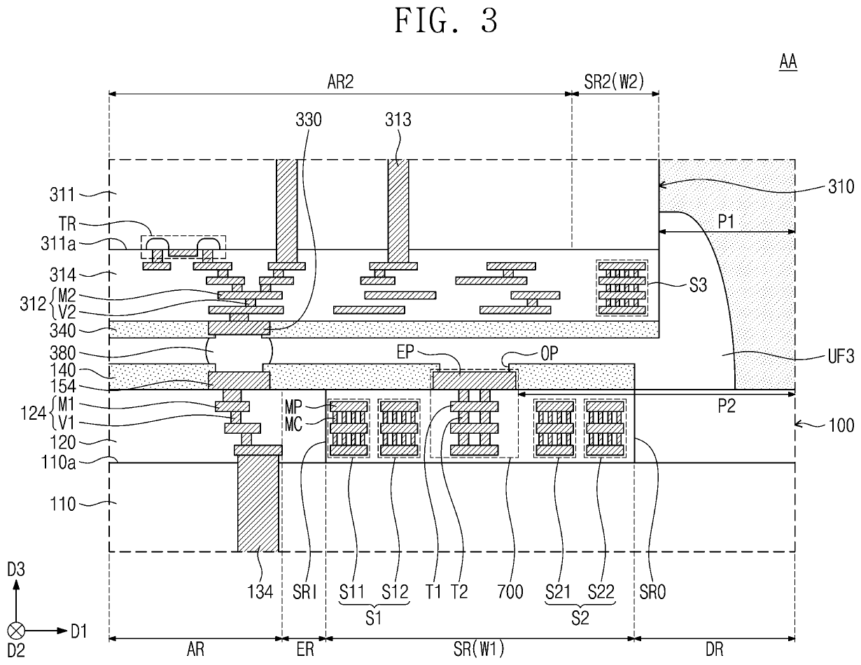

FIG. 3 is an enlarged view showing section AA of FIG. 2.

Referring to FIG. 3, the upper dielectric layer 120 may include a first wiring region AR, an intermediate region ER, a first scribe lane region SR, and a dummy region DR. The first wiring region AR and the first scribe lane region SR may correspond to the wiring region AR and the scribe lane region SR that are discussed in FIG. 2.

A first wiring structure 124 may be disposed on the first wiring region AR. The first wiring structure 124 may correspond to the wiring structure 124 of FIG. 2. A portion of the first wiring structure 124 may electrically connect the first through electrode 132 to the first upper pad 152, another portion of the first wiring structure 124 may electrically connect the second through electrode 134 to the second upper pad 154, and still another portion of the first wiring structure 124 may electrically connect the first upper pad 152 to the second upper pad 154. The first wiring structure 124 may include a plurality of first wiring lines M1 and first vias V1 that connect the first wiring lines M1 to each other.

The first scribe lane region SR may be provided thereon with a first seal ring group S1, a second seal ring group S2, and at least one inspection pattern 700. Each of the first and second seal ring groups S1 and S2 may include a single or plurality of seal rings. For example, the first seal ring group S1 may include a first seal ring S11 and a second seal ring S12. The second seal ring group S2 may include a third seal ring S21 and a fourth seal ring S22. Each of the first, second, third, and fourth seal rings S11, S12, S21, S22 may include a plurality of ring-shaped metal plates MP that are stacked and a plurality of metal connectors MC that connect the metal plates MP to each other. The first, second, third, and fourth seal rings S11, S12, S21, and S22 may serve as buffers that prevent propagation of crack in the wiring region AR during a wafer sawing process. For example, the first, second, third, and fourth seal rings S11, S12, S21, and S22 may protect the wiring structure 124 of the wiring region AR against mechanical stress and damage caused by cracking or peeling during a sawing process. The first, second, third, and fourth seal rings S11, S12, S21, and S22 may be electrically insulated.

The first seal ring group S1 and the second seal ring group S2 may be spaced apart from each other in the first direction D1. The inspection pattern 700 may be disposed between the first seal ring group S1 and the second seal ring group S2. According to some embodiments, the second seal ring group S2 may be omitted. According to some embodiments, the scribe lane region SR may be provided therein with an additional seal ring group that at least partially surrounds the second seal ring group S2. According to some embodiments, each of the first and second seal ring groups S1 and S2 may include a single seal ring.

The inspection pattern 700 may include a test element group (TEG), a wafer alignment key, and/or an overlay mask. Based on its use, the inspection pattern 700 may be electrically connected to or insulated from the wiring structure 124. The inspection pattern 700 may include an exposure pattern EP at an upper portion thereof. For example, when the inspection pattern 700 is a test element group, the exposure pattern EP may be a test pad that can be electrically connected to an external inspection apparatus.

The inspection pattern 700 may include, for example, a plurality of metal patterns T1 and intermediate plugs T2 that connect the metal patterns T1 to each other.

A first passivation layer 140 may be disposed on the upper dielectric layer 120. The first passivation layer 140 may expose the dummy region DR while covering the first wiring region AR, the intermediate region ER, and the first scribe lane region SR1. The first passivation layer 140 may have one or more openings OP, and each of the openings OP may expose the first upper pad 152, the second upper pad 154, and the exposure pattern EP. The first passivation layer 140 may include a dielectric material different from that of the upper dielectric layer 120. The first passivation layer 140 may include, for example, a silicon nitride layer. The first passivation layer 140 may prevent introduction of external moisture into the wiring region AR and the scribe lane region SR. As the first passivation layer 140 is not provided on the dummy region DR, the first passivation layer 140 on the scribe lane region SR and the wiring region AR may be prevented from being damaged when a sawing process is performed on the dummy region DR as discussed below.

The second semiconductor chip 310 may include a second semiconductor substrate 311, an integrated circuit, a lower dielectric layer 314, through electrodes 313, a second wiring structure 312, a second chip pad 330, a second passivation layer 340, and a third seal ring group S3.

The second semiconductor substrate 311 may include a semiconductor, such as silicon or germanium, and may be, for example, a silicon substrate. The integrated circuit may include elements such as a transistor TR, and may be provided on one surface 311a of the second semiconductor substrate 311. The lower dielectric layer 314 may be disposed on the one surface 311a of the second semiconductor substrate 311.

The lower dielectric layer 314 may include a second wiring region AR2 and a second scribe lane region SR2. Unlike the upper dielectric layer 120 of the interposer 100, the lower dielectric layer 314 might not include the dummy region DR. The second wiring structure 312 may be disposed on the second wiring region AR2. The second wiring structure 312 may include a plurality of second wiring lines M2 and a plurality of second vias V2 that connect the second wiring lines M2 to each other.

The third seal ring group S3 may be disposed on the second scribe lane region SR2. The third seal ring group S3 may have a seal ring whose shape is similar to that of seal rings of the first and second seal ring groups S1 and S2. Unlike the first scribe lane region SR1, the second scribe lane region SR2 might not include the inspection pattern 700 or may include an inspection pattern in a cut state. This may be caused by the fact that the second scribe lane region SR2 undergoes a sawing process for forming the second semiconductor chip 310.

The first scribe lane region SR1 may have a first width W1 in the first direction D1, and the second scribe lane region SR2 may have a second width W2 in the first direction D1. The second width W2 may be less than the first width W1. The first width W1 may be an interval between the inner edge SRI and the outer edge SRO of the first scribe lane region SR1. The second width W2 may be an interval between an inner edge and an outer edge of the second scribe lane region SR2.

The through electrodes 313 may penetrate the second semiconductor substrate 311 and may be electrically connected to the second wiring structure 312. The second wiring structure 312 may include a through electrode 313, a second chip pad 330, and an integrated circuit.

The second passivation layer 340 may be disposed on the lower dielectric layer 314. The second passivation layer 340 may expose the second chip pad 330. The second passivation layer 340 may include a material the same as or similar to that of the first passivation layer 140.

A second spacing distance P2 between the inspection pattern 700 and an extension surface that extends from one lateral surface of the interposer 100 may be greater than a first spacing distance P1 between the extension surface and its adjacent lateral surface of the second semiconductor chip 310.

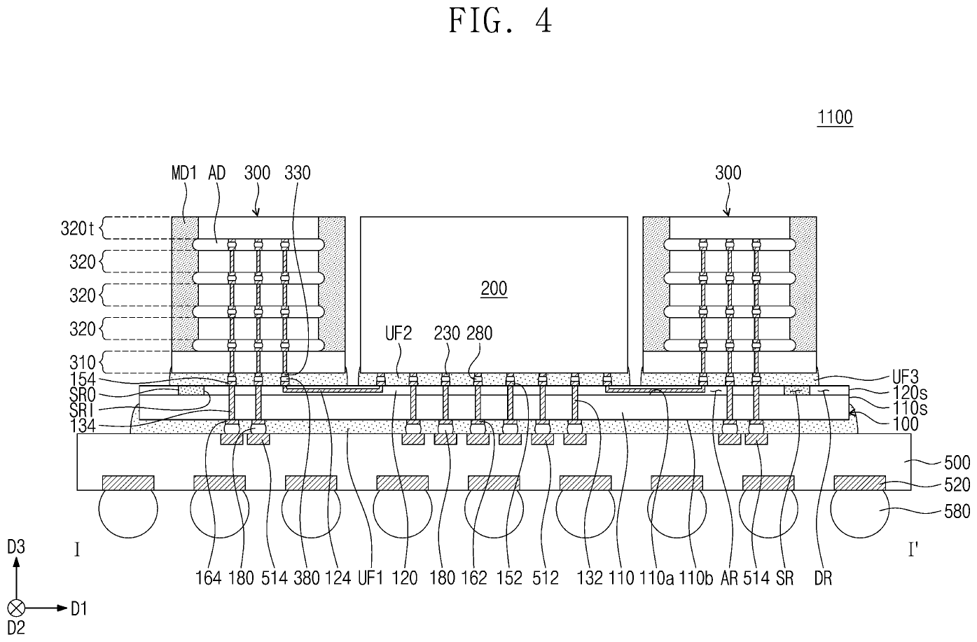

FIG. 4 is a cross-sectional view showing a semiconductor package according to some embodiments of the present inventive concepts. Except that discussed below, omission will be made to avoid a description of components discussed above in FIGS. 1 to 3 and therefore, it is to be understood that any element not described in detail with respect to FIG. 4 may be understood to be at least similar to corresponding elements described with respect to FIGS. 1 to 3.

Referring to FIG. 4, a semiconductor package 1100, according to some embodiments, may be configured such that the second mold structure MD2 may be omitted.

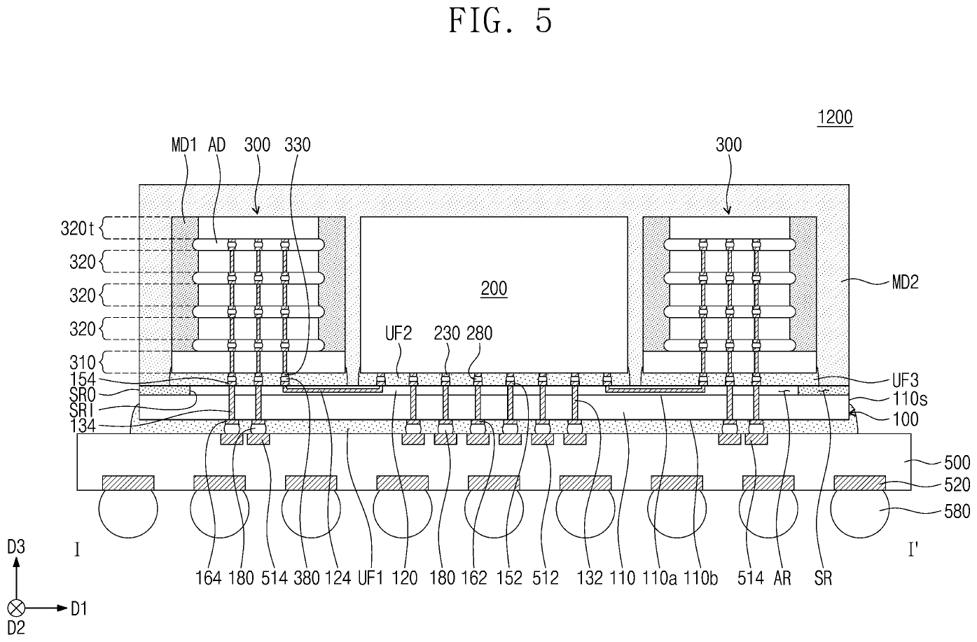

FIG. 5 is a cross-sectional view showing a semiconductor package according to some embodiments of the present inventive concepts. Except that discussed below, omission will be made to avoid a description of components discussed above in FIGS. 1 to 3 and therefore, it is to be understood that any element not described in detail with respect to FIG. 5 may be understood to be at least similar to corresponding elements described with respect to FIGS. 1 to 3.

Referring to FIG. 5, a semiconductor package 1200, according to some embodiments, may be configured such that the upper dielectric layer 120 of the interposer 100 might not include the dummy region DR.

The inner edge SRI of the scribe lane region SR may be disposed immediately below the sub-semiconductor package 300, and the outer edge SRO of the scribe lane region SR may be disposed spaced apart in a diagonal direction from the sub-semiconductor package 300. The outer edge SRO of the scribe lane region SR may be coplanar with the lateral surface 110s of the first semiconductor substrate 110.

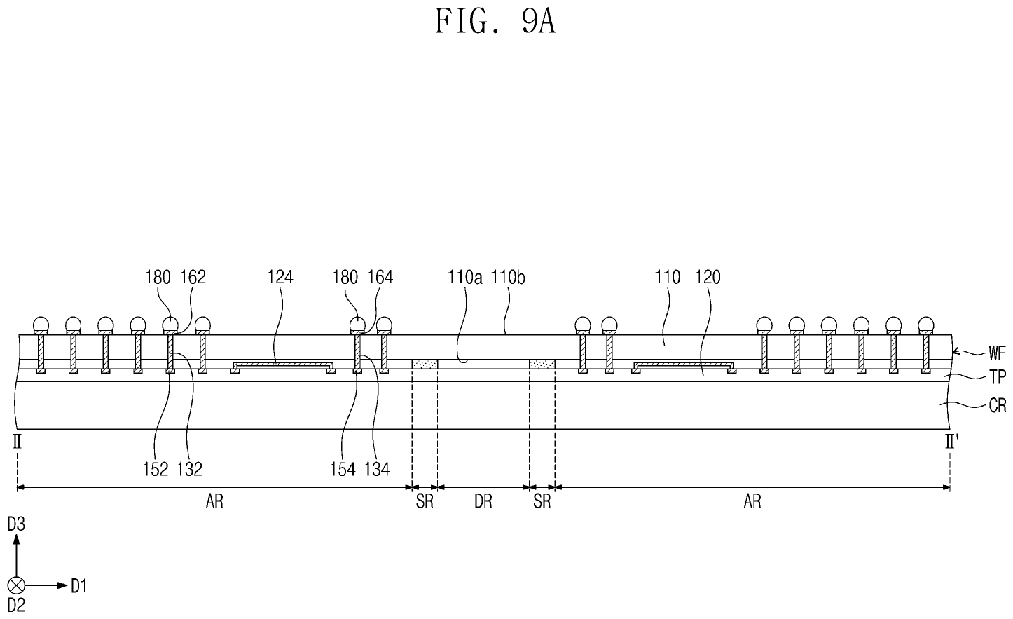

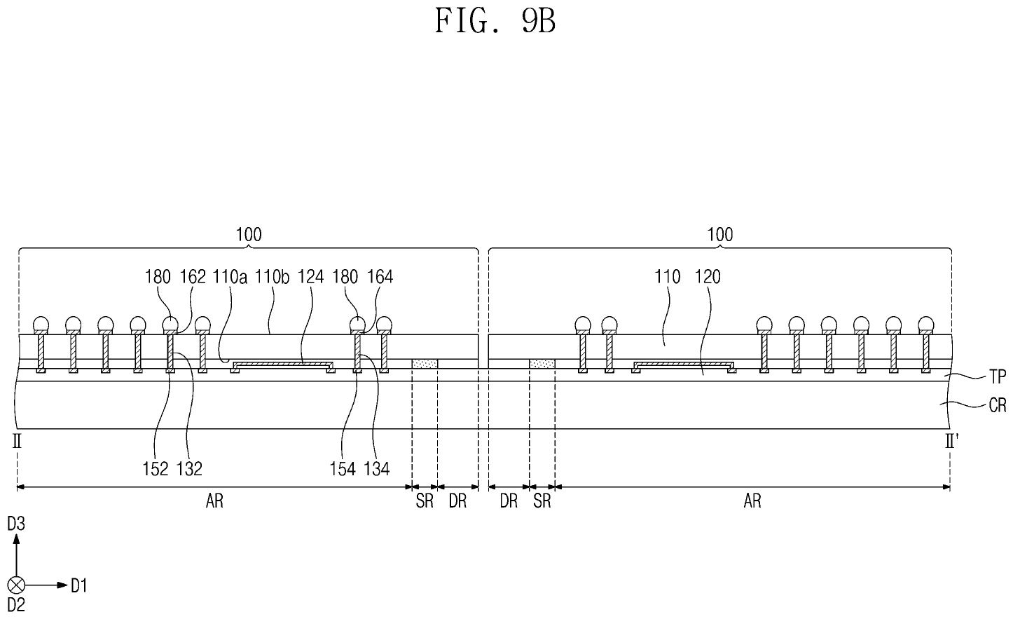

The dummy region DR may all be removed in a procedure where a wafer WF is diced as discussed in FIGS. 9A and 9B, and thus the dummy region DR may be absent in the interposer 100.

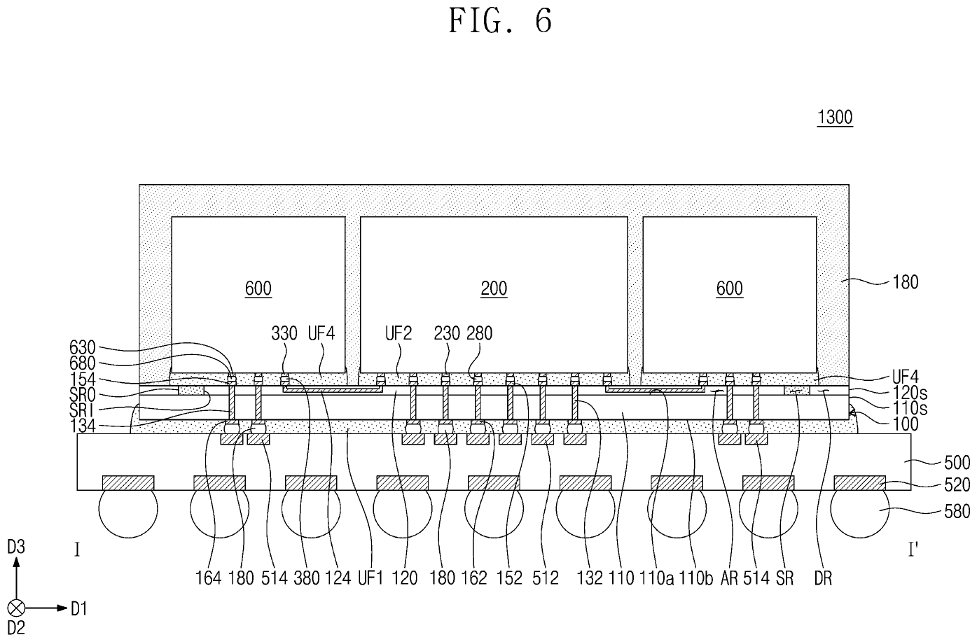

FIG. 6 is a cross-sectional view showing a semiconductor package according to some embodiments of the present inventive concepts. Except that discussed below, omission will be made to avoid a description of components discussed above in FIGS. 1 to 3.

Referring to FIG. 6, a semiconductor package 1300, according to some embodiments, may be configured such that the sub-semiconductor packages 300 may be replaced with at least one dummy chip 600.

The dummy chip 600 might not include any of the second wiring structure 312 and an integrated circuit such as the transistor TR of FIG. 3. The dummy chip 600 may include a semiconductor substrate, a dielectric layer that covers one surface of the semiconductor substrate, and dummy pads 630 disposed on the dielectric layer. The dummy pads 630 may be in direct contact with the semiconductor substrate. Heat transfer terminals 680 may be correspondingly disposed on the dummy pads 630. The heat transfer terminal 680 may include an electrically conductive material, such as a solder ball.

The heat transfer terminal 680 may provide the dummy chip 600 with heat of the interposer 100, and thus the interposer 100 may be prevented from warpage. Alternatively, the dummy chip 600 may receive heat transferred through the wiring structure 124 and the heat transfer terminal 680 from the first semiconductor chip 200, and thus the first semiconductor chip 200 may have a reduced temperature.

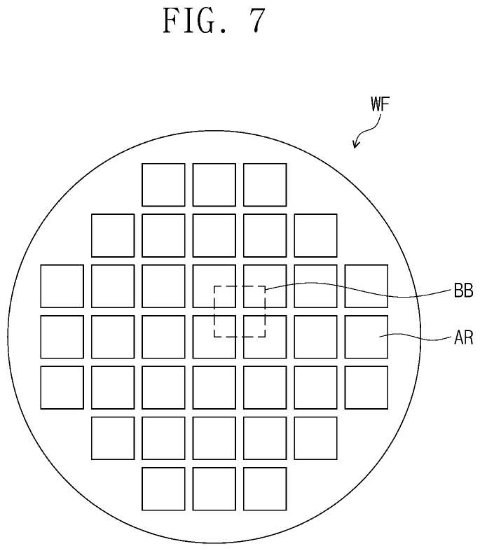

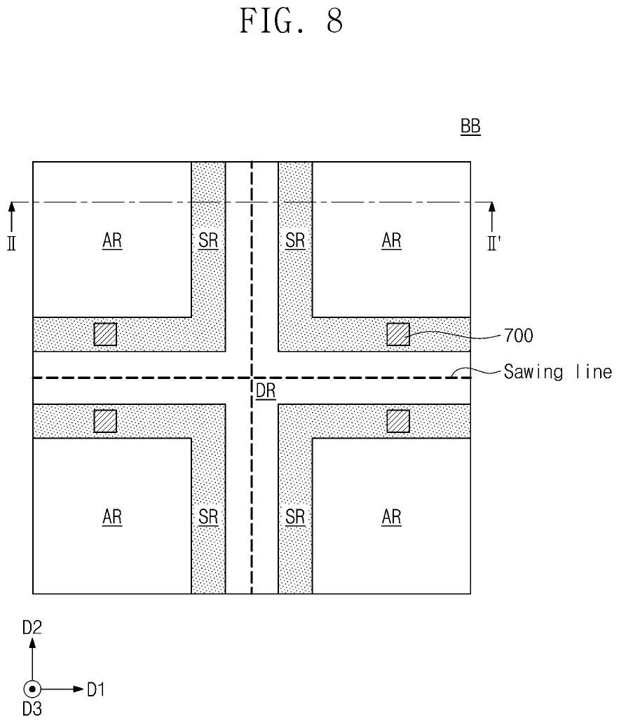

FIG. 7 is a plan view showing a wafer prior to sawing. FIG. 8 is an enlarged view showing section BB of FIG. 7.

Referring to FIGS. 7 and 8, a wafer WF may be provided which includes a plurality of wiring regions AR that are divided by the scribe lane region SR. The scribe lane region SR may have a tetragonal ring shape that at least partially surrounds the wiring region AR. The inspection pattern 700 may be exposed on a surface of the scribe lane region SR. The scribe lane region SR may be divided by the dummy region DR.

The dummy region DR may have a grid shape on the wafer WF. For example, the dummy region DR may have a shape obtained by combining first lines extending in the first direction D1 while being spaced apart in the second direction D2 with second lines extending in the second direction D2 while being spaced apart in the first direction D1.

FIGS. 9A and 9B are cross-sectional views showing a method of fabricating an interposer according to some embodiments of the present inventive concepts. FIG. 9A is a cross-sectional view taken along line II-II′ of FIG. 8.

Referring to FIGS. 8 and 9A, a wafer WF may be attached through a tape TP onto a carrier substrate CR.

The wafer WF before being diced may include a first semiconductor substrate 110, first through electrodes 132, second through electrodes 134, an upper dielectric layer 120, a wiring structure 124, first upper pads 152, second upper pads 154, first lower pads 162, second lower pads 164, and first connection terminals 180. The upper dielectric layer 120 may include a pair of scribe lane regions SR and one dummy region DR between a pair of wiring regions AR.

The dummy region DR may include one region through which a sawing line passes. In this disclosure, the sawing line may be an imaginary line. A stealth sawing process or a blade sawing process may be performed to cut the wafer WF along the sawing line.

The first semiconductor substrate 110 may have a first surface 110a and a second surface 110b that face each other. The upper dielectric layer 120 may be provided on the first surface 110a of the first semiconductor substrate 110. The first through electrodes 132 and the second through electrodes 134 may penetrate the first semiconductor substrate 110. The first upper pads 152 may be correspondingly disposed on one ends of the first through electrodes 132, and the first lower pads 162 may be correspondingly disposed opposite ends of the first through electrodes 132. The second upper pads 154 may be correspondingly disposed on one ends of the second through electrodes 134, and the second lower pads 164 may be correspondingly disposed on opposite ends of the second through electrodes 134. The first connection terminals 180 may be correspondingly disposed on the first lower pads 162 and the second lower pads 164.

Referring to FIGS. 9A and 9B, a sawing process may be performed on the wafer WF along the sawing line.

The dummy region DR of the wafer WF may be partially removed. Alternatively, the dummy region DR of the wafer WF may be totally removed (see FIG. 5). The wafer WF may be sawed into a plurality of interposers 100.

Referring back to FIG. 2, the interposer 100 may be attached onto a package substrate 500. A first semiconductor chip 200 and a plurality of sub-semiconductor packages 300 may be attached onto the interposer 100. One or more of the sub-semiconductor packages 300 may be replaced with dummy chips 600 (see FIG. 6). Alternatively, a semiconductor chip may be disposed which is of a different type from the first semiconductor chip 200.

A first underfill pattern UF1 may be formed between the package substrate 500 and the interposer 100. A second underfill pattern UF2 may be formed between the interposer 100 and the first semiconductor chip 200. A third underfill pattern UF3 may be formed between the interposer 100 and the sub-semiconductor package 300.

An underfill material may be introduced to form the first, second, and third underfill patterns UF1, UF2, and UF3. When the second underfill pattern UF2 and the third underfill pattern UF3 are formed, a keep out zone may be provided on at least a portion of the scribe lane region SR and the dummy region DR. In this disclosure, the keep out zone may correspond to a region required for an underfill process.

As an underfill material is introduced onto the dummy region DR and moves onto the scribe lane region SR and the wiring region AR, a space between the interposer 100 and the sub-semiconductor package 300 may be filled with the underfill material to form the third underfill pattern UF3. As an underfill material is introduced onto the dummy region DR and moves onto the scribe lane region SR and the wiring region AR, a space between the interposer 100 and the first semiconductor chip 200 may be filled with the underfill material to form the second underfill pattern UF2.

A second mold structure MD2 may cover the interposer 100, the first semiconductor chip 200, and the sub-semiconductor packages 300. A semiconductor package 1000 may therefore be formed. According to some embodiments, the formation of the second mold structure MD2 may be omitted (see FIG. 4).

To satisfy the demand for high performance, a logic chip may need an increase in size and an interposer may also need an increase in size.

However, when a large-sized interposer is formed, a mask stitch process down to a reticle size limit may be needed when a wiring region is formed. For example, when one-time photolithography process is needed to form one wiring layer, it may be needed that a photolithography process be performed twice in a case of an increase in size of the interposer. As a result, there may occur problems such as an increase in process cost and a reduction in quality due to time delay between processes.

According to the present inventive concepts, as the interposer includes a sub-scribe lane region and a dummy region, the interposer may become large in total size without increasing an area of the wiring region.

In addition, only the scribe lane region may be present without the dummy region between the wiring regions in an ordinary wafer sawing process. When an underfill material is introduced into a space between a sub-semiconductor package and the interposer that is diced on along the scribe lane region, it may be difficult to increase a size of a first semiconductor chip so as to securely obtain a keep out zone.

According to present inventive concepts, when an underfill material is introduced into a space between the sub-semiconductor package and the interposer that is diced along the dummy region, a keep out zone may be secure on a residual dummy region of the interposer and thus a large-sized first semiconductor chip may be adopted. Therefore, the scribe lane region may be disposed immediately below the first semiconductor chip or the sub-semiconductor package.

According to some embodiments of the present inventive concepts, it may be possible to increase a size of the interposer while minimizing a mask stitch process.

In a semiconductor package, according to some embodiments of the present inventive concepts, an interposer may include a sub-scribe lane region and a dummy region. Thus, the interposer may increase in size without increasing an area of a wiring region of the interposer. A large-sized high performance logic chip may be mounted on the large-sized interposer, and as a result the semiconductor package may increase in performance.

This detailed description of the present inventive concepts should not necessarily be construed as limited to the embodiments set forth herein, and it is intended that the present inventive concepts cover the various combinations, the modifications and variations of this invention without departing from the spirit and scope of the present disclosure.

What is claimed is:

1. A semiconductor package, comprising:
a package substrate;
an interposer disposed on the package substrate; and
a first semiconductor chip disposed on the interposer,
wherein the interposer includes:
a first semiconductor substrate; and
a first dielectric layer disposed on the first semiconductor substrate,
wherein the first dielectric layer includes a first scribe lane region,
wherein the first scribe lane region is below the first semiconductor chip along a first direction that is perpendicular to a top surface of the first semiconductor substrate, and
wherein the first scribe lane region is spaced apart from a lateral surface of the interposer.

2. The semiconductor package of claim 1, wherein the first scribe lane region has a tetragonal ring shape having an inner edge and an outer edge, and
wherein the inner edge and the outer edge each overlap the first semiconductor chip.

3. The semiconductor package of claim 1, wherein the first scribe lane region has a tetragonal ring shape having an inner edge and an outer edge, and
wherein the inner edge overlaps the first semiconductor chip, and the outer edge is exposed by the first semiconductor chip.

4. The semiconductor package of claim 1, wherein the first dielectric layer further includes a dummy region that at least partially surrounds the first scribe lane region, and
wherein at least a portion of the dummy region is positioned in a diagonal direction with respect to the first semiconductor chip.

5. The semiconductor package of claim 4, wherein the interposer further includes an inspection pattern disposed on the first scribe lane region, and
wherein the inspection pattern includes a test element group and/or a wafer alignment key.

6. The semiconductor package of claim 5, further comprising a passivation layer that covers the first dielectric layer,
wherein the inspection pattern includes an exposure pattern, and
wherein the exposure pattern is exposed by the passivation layer.

7. The semiconductor package of claim 6, wherein the passivation layer covers the first scribe lane region and exposes the dummy region.

8. The semiconductor package of claim 1, wherein the first semiconductor chip includes:
a second semiconductor substrate; and
a second dielectric layer disposed on the second semiconductor substrate,
wherein the second dielectric layer includes a second scribe lane region,
wherein the first scribe lane region has a first width in a second direction parallel to the top surface of the first semiconductor substrate,
wherein the second scribe lane region has a second width in the second direction, and
wherein the first width is greater than the second width.

9. A semiconductor package, comprising:
a package substrate;
an interposer disposed on the package substrate; and
a semiconductor chip disposed on the interposer,
wherein the interposer includes:
a first semiconductor substrate; and
a first dielectric layer disposed on the first semiconductor substrate,
wherein the first dielectric layer includes:
a wiring region;
a scribe lane region that at least partially surrounds the wiring region; and
a dummy region that at least partially surrounds the scribe lane region,
wherein at least a portion of the dummy region at least partially surrounds the semiconductor chip.

10. The semiconductor package of claim 9, wherein
a lateral surface of the first semiconductor substrate is coplanar with a lateral surface of the first dielectric layer, and
wherein the lateral surface of the first dielectric layer is an outer edge of the dummy region.

11. The semiconductor package of claim 9, further comprising an underfill pattern disposed between the semiconductor chip and the interposer,
wherein the underfill pattern covers the dummy region.

12. The semiconductor package of claim 9, wherein the interposer further includes an inspection pattern disposed on the scribe lane region,
wherein the inspection pattern includes a test element group and/or a wafer alignment key, and
wherein the inspection pattern vertically overlaps the semiconductor chip.

13. The semiconductor package of claim 9, wherein the semiconductor chip is a logic chip or a memory chip.

14. The semiconductor package of claim 9, wherein the semiconductor chip is a dummy chip, and
wherein the dummy chip includes:
a second semiconductor substrate; and
a metal pad in direct contact with the second semiconductor substrate.

15. A semiconductor package, comprising:
a package substrate;
an interposer disposed on the package substrate;
a logic chip disposed on the package substrate; and
a pair of sub-semiconductor packages that are spaced apart in a first direction from each other across the logic chip,
wherein each of the sub-semiconductor packages includes:
a base chip;
a memory chip stack disposed on the base chip; and
a first mold structure that covers the base chip and the memory chip stack,
wherein the interposer includes an inspection pattern disposed on an upper portion of the interposer,
wherein the inspection pattern includes a test element group and/or a wafer alignment key, and
wherein a second spacing distance between the inspection pattern and a lateral surface of the interposer is greater than a first spacing distance between a lateral surface of the base chip and an extension surface that extends from the lateral surface of the interposer, the lateral surface of the base chip being adjacent to the extension surface.

16. The semiconductor package of claim 15, further comprising a second mold structure that covers a top surface of the interposer, the logic chip, and the sub-semiconductor packages.

17. The semiconductor package of claim 15, further comprising an underfill pattern disposed between the interposer and the base chip,
wherein the inspection pattern further includes an exposure pattern, and
wherein the underfill pattern covers the exposure pattern.

18. The semiconductor package of claim 17, wherein the interposer further includes a passivation layer, and
wherein the passivation layer exposes the exposure pattern.

19. The semiconductor package of claim 15, wherein
the interposer includes a first seal ring group and a second seal ring group that are spaced apart in a first direction from each other across the inspection pattern, the first direction being parallel to the interposer, and
each of the first and second seal ring groups includes at least one seal ring.

20. The semiconductor package of claim 19, wherein the first seal ring group and the second seal ring group vertically overlap the base chip.
